(19) United States
(12) Patent Application Publication
(10) Pub. No.: US 2016/0284545 A1
(43) Pub. Date: Sep. 29, 2016

(54) SYSTEM AND METHOD FOR PRODUCING POLYCRYSTALLINE GROUP III NITRIDE ARTICLES AND USE THEREOF IN PRODUCTION OF SINGLE CRYSTAL GROUP III NITRIDE ARTICLES

(71) Applicant: Hexatech, Inc., Morrisville, NC (US)

(72) Inventors: Raoul Schlesser, Raleigh, NC (US); Edward A. Preble, Raleigh, NC (US)

(73) Assignee: Hexatech, Inc.

(21) Appl. No.: 15/077,057

(22) Filed: Mar. 22, 2016

Related U.S. Application Data
(60) Provisional application No. 62/138,171, filed on Mar. 25, 2015.

(51) Int. Cl. H01L 21/02; H01L 29/04; H01L 29/20

(52) U.S. Cl. CPC H01L 21/02645; H01L 21/0254; H01L 21/02595; H01L 21/02609; H01L 29/2003; H01L 29/04; H01L 29/045

(57) ABSTRACT

The present disclosure relates to processes for producing single crystal Group III Nitride articles, polycrystalline Group III Nitride source materials suitable for use in such processes, and processes for producing polycrystalline Group III Nitride articles suitable for use as such source materials. The polycrystalline Group III Nitride source material can particularly be a grown material formed by vapor deposition methods, such as hydride vapor phase epitaxy (HYPE), and can be characterized by parameters such as purity, N/Al molar ratio, and relative density that are within defined ranges.

### CROSS-REFERENCE TO RELATED APPLICATIONS

The present application claims priority to U.S. Provisional Patent Application No. 62/138,171, filed Mar. 25, 2015, the disclosure of which is incorporated herein by reference.

### FIELD OF THE DISCLOSURE

The present disclosure relates to polycrystalline Group III Nitride articles, and methods of formation thereof, the polycrystalline Group III Nitride articles being suitable for use as a source material in the production of single crystal Group III Nitride articles.

### BACKGROUND

Physical vapor transport (PVT) growth of a single crystal aluminum nitride (AlN) article generally involves the transport of an AlN source material through a temperature gradient to be deposited on a seed crystal or otherwise in a deposition zone, such as within a crucible. In such processes, the starting and evolving condition of the AlN source material is critical to the end result of the transport process. Fundamental parameters of the AlN source material, such as purity, density, grain/particle size, porosity, and thermal conductivity, influence how the PVT process proceeds. Likewise, the nature of the resulting single crystal AlN article can be impacted by the repeatability of the nature of the AlN source material used in individual PVT growth runs as well as the stability of the AlN source material during the course of a PVT growth run. Run stability and repeatability present a challenge in relation to the production of AlN source charges in light of the breakdown of system internal parts caused by the extreme PVT process temperatures (i.e., >2000° C.) and the presence of highly reactive aluminum vapor. Additional challenges include the difficulty of controllably doping or controllably purifying an AlN source material for use in PVT due to the high vapor pressure of most dopant candidates at temperatures greater than 2000° C., which limits the feasibility of dopant incorporation in the growing crystal, as well as the challenge of transporting large volumes of material during a single run because of growth rate and gradient limitations when larger crucible dimensions are employed.

It would be desirable to exclude certain polycrystalline AlN production processes that have been shown statistically to cause crystal growth defects when used as source material in single crystal PVT AlN growth. In particular, the use of AlN powder, which typically has 1% or more impurity content, as well as low relative density of only 40-60%, tends to induce polycrystalline growth and increase the frequency of misoriented grains in single crystal PVT AlN growth. Sintering treatment of AlN powder, with or without binders, is still not adequate for consistently high-yield defect-free growth of single crystal PVT AlN. Typical sintered AlN materials can have improved purity (e.g., 99.9%) and higher density (e.g., 66% +/−6%), but this is still inadequate for use as source material in subsequent single crystal PVT AlN growth.

In light of the desirable properties of AlN articles, there is a need for production of single crystal AlN articles of increased size, which likewise drives a need for larger volumes of AlN source materials for use in single crystal AlN growth processes, such as PVT. Presently, AlN source materials can be prepared, for example, utilizing an AlN powder sublimation/condensation purification scheme. While such methods can be useful in small batch runs and for preparing relatively small sized AlN articles, processing of large volumes of AlN source material in such manner can be cost and time intensive utilizing reactor time that may otherwise be used in single crystal AlN PVT growth. Further, evaporative losses of source material during such purification schemes are magnified by increasing the volume of the source material being processed. Accordingly, there is a need in the art for additional AlN source materials and production strategies that are suitable for use in the growth of single crystal AlN articles and other Group III Nitrides.

### SUMMARY OF THE DISCLOSURE

The present disclosure relates to processes for producing single crystal Group III Nitride articles, polycrystalline Group III Nitride source materials suitable for use in such processes, and processes for producing polycrystalline Group III Nitride articles suitable for use as such source materials. In exemplary embodiments, the Group III Nitride can be Aluminum Nitride (AlN).

Polycrystalline AlN articles can be prepared in large volumes with high relative density, low porosity, and desirable stoichiometry. The processes by which the polycrystalline AlN articles are prepared can exhibit high growth rates and allow for controllable doping of growing crystals to modify crystal properties, such as electrical and optical parameters. The polycrystalline AlN articles are specifically adapted for use as a source material in the preparation of single crystal AlN articles, such as by physical vapor deposition (PVT), and improve run stability and repeatability in such single crystal growth processes.

In some embodiments, the present disclosure can relate to processes for the preparation of polycrystalline AlN articles. The methods particularly can include growth methods, such as vapor phase growth methods, liquid phase growth methods, solid phase methods, and plasma growth methods. The methods also can include growth methods using combinations of the different phases. The growth methods can be characterized in terms of the nature of the polycrystalline AlN articles produced thereby. In particular, the polycrystalline AlN articles can be especially suitable for use as a source material in physical vapor transport (PVT) growth of a single crystal AlN article.

In some embodiments, the present disclosure can relate to a source material adapted for use in a PVT growth process. The source material particularly can comprise a grown polycrystalline AlN mass. For example, the polycrystalline AlN mass can be a mass that has been grown to have a specific thickness as described herein (e.g., about 2 cm or greater), can be a mass that has been grown to have at least one lateral dimension as described herein (e.g., about 10 cm or greater), can be a mass that has been grown to have an N/Al molar ratio as described herein (e.g., about 1), can be a mass that has been grown to have a relative density (as compared to the theoretical density of single crystalline AlN) as described herein (e.g., at least 98%), can be a mass that is substantially free of aluminum metal inclusions, and/or can be a mass that has been grown to have an aluminum nitride purity as described herein (e.g., at least 99% by weight, preferably at least 99.99% by weight). In one embodiment, a source material adapted for use in a PVT growth process can comprise a grown polycrystalline AlN mass that has been grown to have a thickness of about 2.5 cm or greater, to have at least one lateral dimension of about 12.5 cm or greater, to have an N/Al molar ratio of about 1, to have a relative density of about 99%, and to have an aluminum nitride purity of at least 99% by weight. The grown polycrystalline AlN mass particularly can be a mass that has been grown to have an average grain size as described herein (e.g., about 0.5 mm to about 2 mm).

In some embodiments, a source material can be a grown polycrystalline AlN mass that has been grown to have even further specific purity characteristics. For example, the grown polycrystalline AlN mass can be a mass that has been grown to have one or more of: a carbon content of less than 1000 ppm, a silicon content of less than 1000 ppm, and an oxygen content of less than 1000 ppm. In some embodiments, a grown polycrystalline AlN mass can be a mass that has an unintentional content of carbon in the range of 1e15 to 1e17 atoms/cm³, and/or an unintentional content of oxygen in the range of 1e15 to 1e17 atoms/cm³, and/or an unintentional content of silicon in the range of 1e15 to 1e17 atoms/cm³, as measured by secondary ion mass spectrometry (SIMS). Such ranges particularly may be applicable to Al-face grown HVPE

In some embodiments, the grown polycrystalline AlN mass can be a hydride vapor phase epitaxy (HVPE) grown mass. In further embodiments, the grown polycrystalline AlN mass can be a physical vapor deposition (PVD) grown mass. In additional embodiments, the grown polycrystalline mass can be a physical vapor transport (PVT) grown mass. In yet further embodiments, the grown polycrystalline mass can be a mass grown by metal vaporization and nitridation.

In other embodiments, the present disclosure also can relate to processes for producing a single crystal AlN article. For example, such process can comprise carrying out PVT growth of the single crystal AlN article using a source material comprising a grown polycrystalline AlN mass. In particular, the grown polycrystalline AlN mass can be a mass exhibiting specific properties as otherwise described herein. In some embodiments, the grown polycrystalline AlN mass can be a mass that exhibits one or more of the following properties: a carbon content of less than 1000 ppm; a silicon content of less than 1000 ppm; an oxygen content of less than 1000 ppm; an N/Al molar ratio of about 1; a relative density of about 99%; and an aluminum nitride purity of at least 99% by weight. In further embodiments, the grown polycrystalline AlN mass can be a hydride vapor phase epitaxy (HVPE) grown mass or a physical vapor deposition (PVD) grown mass.

The presently disclosed processes and articles can be described in relation to still further embodiments. For example, one or more of the following may be included in example embodiments of the present disclosure.

The disclosure can relate to a hydride vapor phase epitaxy (HVPE) process for producing a polycrystalline AlN article.

The disclosure can relate to a grown polycrystalline AlN article that exhibits a reduction in impurities relative to an AlN article prepared by PVT or by sintering of AlN powders.

The disclosure can relate to processes for controllably doping a grown AlN article so as to modify electrical and/or optical properties of the AlN.

The disclosure can relate to processes for producing polycrystalline AlN articles at reduced growth temperatures relative to PVT growth methods.

The disclosure can relate to processes for producing polycrystalline AlN articles at reduced temperature and/or pressure relative to methods for sintering AlN powder.

The disclosure can relate to polycrystalline AlN articles and processes for producing such articles having relatively large crystal volumes, such as 150 cm³ or greater or 200 cm³ or greater.

In some embodiments even larger volumes, such as 500 cm³ or greater to about 1500 cm³ or greater, are envisioned.

The disclosure can relate to polycrystalline AlN articles and processes for producing such articles having theoretical or substantially theoretical density.

The disclosure can relate to processes for producing single crystal AlN by PVT using a grown polycrystalline AlN mass as a source material.

The disclosure can relate to pulsed laser deposition (PLD) processes, sputtering processes, or similar processes using a grown polycrystalline AlN mass as a source material.

The disclosure can relate to polycrystalline AlN articles that are free of, or substantially free of, metal inclusions. In particular, the polycrystalline AlN article preferably is free of, or substantially free of, aluminum inclusions.

The disclosure can relate to a process for producing an AlN single crystal via PVT. In particular, the process can comprise: providing an AlN source material and an AlN seed within a reactor in a spaced apart orientation; and heating the AlN source material in a manner sufficient to form volatilized species from the AlN source material for transport to the AlN seed; wherein the AlN source material comprises a grown polycrystalline AlN mass that has been grown to have a thickness of about 2.5 cm or greater, to have at least one lateral dimension of about 3 cm or greater, to have an N/Al molar ratio of about 1, to have a relative density of at least 98%, and to have an aluminum nitride purity of at least 99% by weight.

The disclosure can relate to an AlN single crystal produced according to a process described herein (such as, for example, the process exemplified above), wherein the AlN single crystal is free or substantially free of one or a plurality of the following: inclusions, cracks, misoriented grains, domain boundaries, and polycrystals.

The disclosure can relate to an AlN single crystal produced according to a process described herein (such as, for example, the process exemplified above), wherein the AlN single crystal has an optical absorption coefficient (alpha) at 265 nm of less than 100 cm⁻¹.

The disclosure can relate to an AlN single crystal produced according to a process described herein (such as, for example, the process exemplified above), wherein the AlN single crystal has an average dislocation density that is less than 10⁻⁴ cm⁻² over the entire surface area of a single crystal that is larger than 20 mm diameter.

The disclosure can relate to an AlN single crystal produced according to a process described herein (such as, for example, the process exemplified above), wherein the AlN single crystal has a boule height of greater than 2 cm.

The disclosure can relate to an AlN single crystal produced according to a process described herein (such as, for example, the process exemplified above), wherein the AlN single crystal is larger than 25 mm in diameter and has a top surface entirely free of crystallographic tilt-domains greater than 30 arc-sec as measured by high resolution triple axis x-ray diffraction.

The disclosure can relate to an AlN seed that is derived from an AlN single crystal produced according to a process as described herein (such as, for example, the process exemplified above).

The disclosure can relate to an AlN seed suitable for iterative growth of further generations of AlN single crystals. In particular, the AlN seed can comprise a fraction of a previous generation AlN single crystal; and the (00.2) X-ray diffraction (XRD) full width at half maximum (FWHM) signal intensity for a seed line arising from the AlN seed can change by no more than 10 arc seconds over at least three generations of the iterative growth. Further, the AlN seed can be a fraction of a previous generation AlN single crystal grown by a PVT process using an AlN source material as described herein. Particularly, the AlN source material comprise a grown polycrystalline AlN mass that has been grown to have a thickness of about 2.5 cm or greater, to have at least one lateral dimension of about 3 cm or greater, to have an N/Al molar ratio of about 1, to have a relative density of at least 98%, and to have an aluminum nitride purity of at least 99% by weight.

The disclosure can relate to a process for multi-generational AlN single crystal seeded growth, the process comprising iteratively growing a next generation AlN single crystal using a seed from a previous generation A1N single crystal, said iterative growing utilizing a grown polycrystalline AlN mass of a suitable quality such that physical AlN single crystal size and at least one measure of single crystal AlN crystalline quality does not substantially decrease across at least three generations of the iterative growth. In particular embodiments, the process can be characterized in that (00.2) XRD Rocking curve FWHM for each AlN single crystal arising from the iterative growth changes by no more than 10 arc seconds over at least three generations of the iterative growth. In some embodiments, the process can be characterized in that the grown polycrystalline AlN mass has been grown to have a thickness of about 2.5 cm or greater, to have at least one lateral dimension of about 3 cm or greater, to have an N/Al molar ratio of about 1, to have a relative density of at least 98%, and to have an aluminum nitride purity of at least 99% by weight.

### BRIEF DESCRIPTION OF THE DRAWINGS

Having thus described the disclosure in the foregoing general terms, reference will now be made to the accompanying drawings, which are not necessarily drawn to scale, and wherein:

FIG. 1 is a graph of the (00.2) X-Ray Diffraction (XRD) Rocking curve full width at half maximum (FWHM) for a multi-generational line of single crystal AlN produced according to exemplary embodiments of the present disclosure; and

FIG. 2 is a graph of the (10.2) XRD Rocking curve FWHM for a multi-generational line of single crystal AlN produced according to exemplary embodiments of the present disclosure.

### DETAILED DESCRIPTION

The present disclosure will now be described more fully hereinafter with reference to exemplary embodiments thereof. These exemplary embodiments are described so that this disclosure will be thorough and complete, and will fully convey the scope of the disclosure to those skilled in the art. Indeed, the disclosure may be embodied in many different forms and should not be construed as limited to the embodiments set forth herein; rather, these embodiments are provided so that this disclosure will satisfy applicable legal requirements. As used in the specification, and in the appended claims, the singular forms “a”, “an”, “the”, include plural referents unless the context clearly dictates otherwise.

In various embodiments, the present disclosure relates to aluminum nitride (AlN) articles and methods of preparation thereof. It is understood that such disclosure is exemplary of the systems and processes in relation to Group III Nitrides, and the exemplary embodiments may thus be extended to other Group III Nitrides, such as gallium nitride.

In some embodiments, the present disclosure relates to processes for producing a polycrystalline AlN mass. The polycrystalline AlN mass produced by such methods is a solid article of defined dimensions as otherwise disclosed herein. As such, in some embodiments, the polycrystalline AlN mass may be described as excluding AlN powder.

Processes for producing a polycrystalline AlN mass can particularly include growth processes whereby the AlN mass is grown from gaseous precursors—e.g., a vapor phase growth process. In some embodiments, epitaxial growth processes may be used. Alternatively, vapor deposition processes can be used. In one embodiment, a polycrystalline AlN mass can be prepared using a physical vapor deposition (PVD) process. In one preferred embodiment, a polycrystalline AlN mass can be prepared using hydride vapor phase epitaxy (HVPE).

As an exemplary embodiment, HVPE growth of AlN can comprise the formation of gaseous aluminum chlorides (e.g., AlCl₃ and AlCl) using pure aluminum metal source material that is reacted with a reactive chlorinated material (e.g., gas phase chlorine or hydrogen chloride). The gaseous aluminum chlorides are transported to a deposition zone for further reaction with a nitrogen source (e.g., NH₃) to form solid AlN. A carrier gas (e.g., N₂, H₂, argon, or another chemically non-contributing species) can be used to facilitate transport to the deposition zone. An HVPE growth process can be carried out at a temperature in the range of about 900° C. to about 1500° C., and known reactor systems and materials that are chemically and thermally stable in this temperature range can be used. The polycrystalline AlN mass can be grown on any suitable substrate (e.g., sapphire, SiC, AlN, GaN, Si, Quartz) that preferably is thermally matched (e.g., in relation to thermal expansion) to the AlN mass being grown. A suitable reactor for carrying out HVPE can be, for example, a cold walled chemical vapor deposition reactor. Examples of HVPE methods and reaction conditions that may be useful according to the present disclosure are described in U.S. Pat. Nos. 8,435,879, 6,943,095, 6,676,751 and 6,440,823, the disclosures of which are incorporated herein by reference in their entireties.

Starting materials for use in a growth process can be provided in a desirably high purity and/or purified before or during the growth process. As a non-limiting example, for an HVPE growth process, elemental aluminum, hydrogen chloride, gas phase chlorine, and ammonia can be obtained in high purity semiconductor grades from commercial vendors. If further purification is desired, inline purifiers can be utilized for gaseous precursors. The NANOCHEM® MiniSentry™ in-line purifier (available from Matheson Gas, Montgomery, Pa., www.mathesongas.com) and the Gaskleen® II gas purifier (available from Pall Corporation, Port Washington, N.Y., www.pall.com) are examples of inline purifiers suitable for purification of gaseous precursors useful according to the present disclosure. Likewise, aluminum metal can undergo pre-processing steps that are known in the art for removal of surface oxides. For example, a solution and method for removal of aluminum oxide are described in U.S. Pub. No. 2011/0268885, the disclosure of which is incorporated herein by reference in its entirety. Ultra-high purity carrier gases also can be obtained for use in such growth processes. Use of high purity precursors and carriers in a growth process for producing a polycrystalline aluminum nitride mass can beneficially result in exceptionally high purity aluminum nitride articles suitable for use as a source material in the production of single crystal aluminum nitride articles.

Growth processes, such as HVPE, that are used according to the present disclosure can provide a number of advantages over other processes for forming polycrystalline AlN articles, such as sintering. For example, HVPE and like growth processes can provide the ability to controllably dope growing crystals with a wide variety of high purity dopant sources materials (e.g., metals, oxides, nitrides, gases, and metal-organics) to modify crystal properties including, but limited to, electrical parameters and optical parameters. Adjustment of background dopant concentrations in particular can be desirable for optical transparency modification in final substrate materials. Dopant concentrations can be more directly controlled and stabilized in processes that supply growth constituents over time during the crystal growth process (such as gas based HVPE processes), as opposed to processes that are nominally closed systems, such as solid source reactions that do not have real time charge loading or adjusting capability.

As a further example, the present growth processes are advantageous because of the large reaction zones capability for crystal growth, exceeding, for example, 100 cubic inches (1639 cm³). This is a contrast to the typically small sizes (e.g., on the order of only a few cubic inches) of high temperature AlN PVT crucibles.

As yet another example, the present growth processes are advantageous because of the high growth rates that can be achieved. In particular, growth rate may, in some embodiments, be limited only by the transport rate of the reactive species to the crystal growth zone. In particular embodiments, growth rates in excess of 1 mm/hr can be achieved.

Production of polycrystalline AlN utilizing a growth method such as described above can advantageously provide a grown polycrystalline AlN mass that is particularly adapted for use of a source material in the growth of a single crystal AlN article. Characteristics of the grown polycrystalline AlN mass that make it particularly suited for use as a source material can arise directly from the process used in preparing the grown polycrystalline AlN mass.

Typical large volume polycrystalline AlN materials are produced by sintering AlN powders. Materials produced by such sintering processes are not well suited for use as a source material in the growth of a single crystal AlN article. Sintered polycrystalline AlN materials are typically formed with relatively low purity AlN powders that can include a significant amount of oxygen and/or binder materials (e.g., yttria). Such sintered materials likewise often exhibit significant porosities. More particularly, sintered A1N, due to either excessively high oxygen content and/or excessively high internal void content (i.e., low density) can cause growth defects if used in growing single crystal AlN. Because of the conformal gas phase coating that occurs in the growth processes according to the present disclosure, however, the grown polycrystalline AlN masses exhibit many specific properties that make them particularly useful as a source material in the production of single crystal AlN articles.

In some embodiments, a grown polycrystalline AlN mass can be provided with relatively large dimensions. For example, a grown polycrystalline AlN mass can have a thickness of about 2 cm or greater, about 2.5 cm or greater, about 3 cm or greater, or about 4 cm or greater, more particularly in the range of about 0.1 cm to about 10 cm, about 0.5 cm to about 9 cm, about 1 cm to about 8 cm, or about 2.5 cm to about 7.5 cm. In combination with such thickness, a grown polycrystalline AlN mass can have at least one lateral dimension that is about 10 cm or greater, about 12.5 cm or greater, or about 15 cm or greater, more particularly in the range of about 7.5 cm to about 40 cm, about 10 cm to about 35 cm, or about 12.5 cm to about 30 cm. The lateral dimension can be any dimension used in defining the area of a three dimensional mass, such as a length, width, diameter, or the like. For example, in the case of a grown polycrystalline AlN mass substantially in the shape of a disc, the dimensions of the disc can be defined in relation to the thickness and the diameter of the disc (the diameter being the lateral dimension). As another example, in the case of a grown polycrystalline AlN mass substantially in the shape of a rectangle, the dimensions of the disc can be defined in relation to the thickness and one or both of the length and width of the rectangle (the length and the width being the lateral dimensions). In an exemplary embodiment, a grown polycrystalline AlN mass can be substantially in the shape of a disc having a thickness of at about 2 cm or greater (particularly about 2.5 cm to about 2.5 cm to about 7.5 cm) and a diameter of about 10 cm or greater (particularly about 12.5 cm to about 30 cm). As further described herein, the provision of a polycrystalline AlN mass can be particularly advantageous for use in the growth of single crystal AlN, such as via PVT (i.e., the combination of a non-PVT growth process with a PVT growth process to produce a single crystal AlN).

In some embodiments, a grown polycrystalline AlN mass can be characterized in terms of its overall volume alone or in combination with one or more dimensions as discussed above. As non-limiting examples, a grown polycrystalline AlN mass can have a volume of about 500 cm³ or greater, about 750 cm³ or greater, about 1000 cm³ or greater, about 1250 cm³ or greater, or about 1500 cm³ or greater. In some embodiments, a grown polycrystalline AlN mass can have a volume of about 500 cm³ to about 5000 cm³, about 750 cm³ to about 4000 cm³, or about 1000 cm³ to about 3000 cm³.

In addition to overall article size, a grown polycrystalline AlN mass can also be characterized in relation to the average grain size (or particle size) of the individual crystals forming the polycrystalline mass. In some embodiments, grown polycrystalline AlN mass can exhibit an average grain size of about 0.01 mm to about 5 mm, about 0.05 mm to about 4 mm, about 0.1 mm to about 3 mm, or about 0.5 mm to about 2 mm.

A grown polycrystalline AlN mass can also be grown to have a desired nitrogen to aluminum (N/Al) molar ratio. In some embodiments, a grown polycrystalline AlN mass can have an N/Al molar ratio of approximately 1. As such, the grown polycrystalline mass can be free or substantially free of metal inclusions, particularly aluminum metal. Typical growth conditions for achieving stoichiometric aluminum nitride can utilize an oversupply of nitrogen gas, or other nitrogen containing material (e.g., ammonia) since the cracking of nitrogen sources into atomic nitrogen is typically inefficient. Additionally, conditions for producing the grown polycrystalline mass of AlN preferably do not allow growth above the rate at which the formed AlN is free of Al inclusions or inclusions of other materials that may be present in the growth zone of the system.

A grown polycrystalline AlN mass further can have a desired relative density. As used herein, relative density is understood to be a comparative term whereby the density of a polycrystalline material (in mass per unit volume) is compared to the theoretical, 100% density of the material. For example, a single crystal AlN material may be used as a 100% dense basis for evaluating relative density a polycrystalline AlN material. Polycrystalline materials typically are less than 100% dense because of internal porosity and surface porosity. It is preferable, however, for a grown polycrystalline AlN mass to be as close to 100% dense as possible. In some embodiments of the present disclosure, the grown polycrystalline AlN mass can exhibit a relative density of at least about 95%, at least about 98%, at least about 99%, at least about 99.5%, or at least about 99.8%.

It also can be desirable according to some embodiments to provide a grown polycrystalline AlN mass of a defined purity. For example, the grown polycrystalline AlN mass can be substantially free of impurities, such as other metals, carbon, oxygen, silicon, and any other elements or compounds other than aluminum and nitrogen. In exemplary embodiments, a grown polycrystalline AlN mass can have a purity for aluminum nitride of at least about 98%, at least about 99%, at least about 99.9%, at least about 99.99%, or at least about 99.999% by weight.

As discussed above, the presently disclosed methods of preparing a polycrystalline aluminum nitride article useful as a source material can benefit from the ability to controllably dope the grown polycrystalline aluminum nitride mass. As certain dopants may thus be present in a grown polycrystalline aluminum nitride mass according to the present disclosure, the desirably high purity of the mass can be characterized in terms of undesirable species that may be expressly excluded to a defined extent from the grown mass. For example, it can be particularly beneficial to exclude undesirably high concentrations of one or more of carbon, silicon, and oxygen in a grown polycrystalline aluminum nitride mass. In some embodiments, a grown polycrystalline aluminum nitride mass can have a carbon content of less than 1000 ppm, less than 500 ppm, less than 300 ppm, less than 200 ppm, or less than 100 ppm. In some embodiments, a grown polycrystalline aluminum nitride mass can have a silicon content of less than 1000 ppm, less than 500 ppm, less than 300 ppm, less than 200 ppm, or less than 100 ppm. In some embodiments, a grown polycrystalline aluminum nitride mass can have an oxygen content of less than 1000 ppm, less than 500 ppm, less than 300 ppm, less than 200 ppm, or less than 100 ppm.

Production of high purity, high transparency, and high thermal conductivity single crystal aluminum nitride articles using growth techniques such as PVT, pulsed laser deposition (PLD), sputtering, or other like methods requires high purity and high density AlN source material. A grown polycrystalline aluminum nitride mass as described herein is particularly adapted for use as a source material in the production of single crystal aluminum nitride articles.

In some embodiments, the present disclosure thus relates to processes for producing single crystal AlN articles. The single crystal AlN articles produced by such methods exhibit desirable qualities, such as high purity, high transparency, and high thermal conductivity. A “single crystal” or “single crystalline” structure refers to a single crystalline form having sufficient long range order to provide substantially isotropic electronic and/or physical properties along each axis of the crystalline structure.

Any method suitable for growth of a single crystal AlN article may be carried out according to the present disclosure utilizing a polycrystalline AlN mass as described herein. In an exemplary embodiment, a process for producing a single crystal AlN article can comprise PVT growth of the single crystal AlN article using a source material comprising a grown polycrystalline AlN mass as otherwise described herein.

In a non-limiting example, formation of a single crystal AlN article can comprise an integrated seeded growth process using a PVT process wherein a source material and a seed are spaced apart within a crucible and heated in a manner sufficient to sublime the source material such that the volatilized species are transported from the source to the seed and recondensed on the seed. Such PVT process can be practiced using any high-temperature reactor capable of generating seed growth temperatures in the range of about 1900° C. to about 2400° C. In certain embodiments, the reactor may also be capable of operating at a pressure of up to about 1000 Torr. The reactor particularly can be configured to allow for control of the temperature distribution within the reactor such as, for example being configured in a manner capable of establishing an axial temperature gradient (e.g., along the symmetry axis of a cylindrical crucible) which can be inverted during the process. One such process is described in U.S. Pat. No. 7,678,195, the disclosure of which is incorporated herein by reference in its entirety.

Use of a grown polycrystalline AlN mass as described herein as a source material in a PVT process (or other process) in forming a single crystal AlN article can particularly provide the single crystal AlN article in a desirable quality. For example, in some embodiments, a single crystal AlN article grown according to the present disclosure utilizing a grown polycrystalline AlN mass as described herein can exhibit one or more of the following characteristics:
A) a single crystal that is free or substantially free of one of the following, two of any combination of the following, three of any combination of the following, four of any combination of the following, or all of the following: inclusions, cracks, misoriented grains, domain boundaries, and polycrystals;
B) a single crystal that has an optical absorption coefficient (alpha) at 265 nm of less than 100 cm⁻¹, preferably less than 10 cm⁻¹, and more preferably less than 1 cm⁻¹;
C) a single crystal that has an average dislocation density that is less than 10⁴ cm⁻² or less than 10⁻³ cm⁻² over the entire surface area of a crystal that is larger than 20 mm diameter;
D) a single crystal that has a boule height of greater than 2.5 cm;
E) a single crystal that is larger than 25 mm in diameter and that has a top surface entirely free of crystallographic tilt-domains greater than 18 arc-sec as measured by high resolution triple axis x-ray diffraction.

In some embodiments, the present disclosure also provides compositions and processes that allow for improved iterative growth of a plurality of generations of AlN single crystal. It is desirable to reproducibly and iteratively perform PVT single crystal growth over the course of a plurality of generations wherein future generation growth is seeded with material harvested from the AlN single crystal produced in the previous generation. Preferably, such iterative growth can be achieved without degradation of seed quality, seed size, or other desirable seed parameters. Such ability for iterative growth has not previously been realized for various reasons, including the inability to provide AlN source materials of suitable quality. In particular, AlN source materials of insufficient quality can introduce defects into the boule growth. Such defects include, but are not limited to, misoriented grains, and such defects can limit the ability to replicate seeds and expand a manufacturing line via seed multiplication due to a gradual, irrecoverable loss of structural crystal quality.

According to embodiments of the present disclosure, however, it is possible to carry out multi-generational AlN single crystal seeded growth and continuously produce AlN single crystal seeds that support such multi-generational growth without substantial reduction in physical AlN single crystal size and without reduction of various measures of single crystal AlN crystalline quality. This may particularly be achieved because of the high quality imparted by the use of the grown polycrystalline AlN source material otherwise described. Such reproducibility in the iterative growth of single crystal AlN can be realized over at least three generations, at least five generations, at least 10 generations, or at least 15 generations.

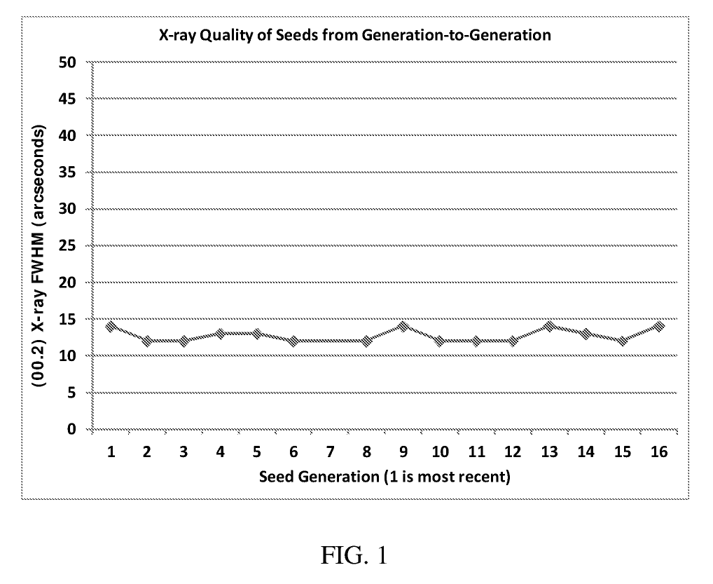

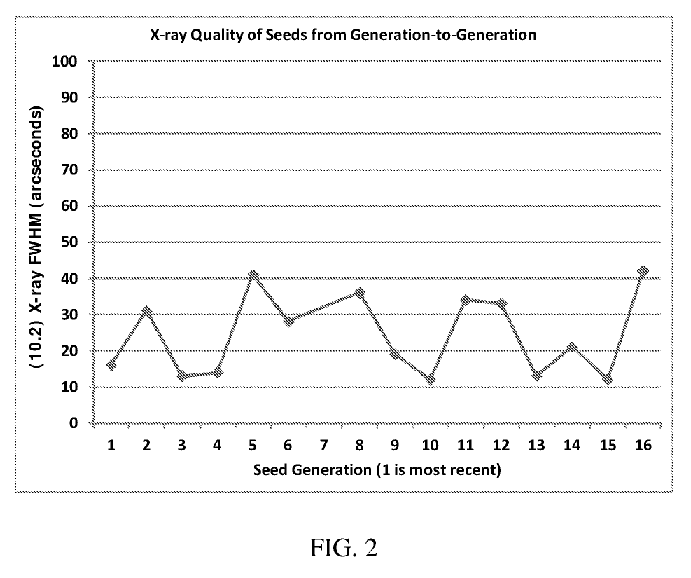

The capability to reproducibly and iteratively perform PVT single crystal AlN growth over the course of a plurality of generations is evidenced in the graphs provided in FIG. 1 and FIG. 2. In particular, an AlN single crystal was prepared using a grown polycrystalline AlN mass as described herein as a source material. A fraction of the AlN single crystal was harvested as a seed for preparation of a next generation AlN single crystal also using a grown polycrystalline AlN mass as described herein as a source material. This process was carried out iteratively for a total of 16 generations wherein future generation single crystal AlN was prepared using a seed from a previous generation single crystal AlN. To evaluate the quality of the single crystal AlN in each of the iterative generations, samples were subjected to X-Ray Diffraction (XRD), and the Rocking curve full width at half maximum (FWHM) for each sample was recorded for the (00.2) reflection and the (10.2) reflection.

As seen in FIG. 1, the (00.2) Rocking curve FWHM for the samples in generations 1 through 16 was consistently in the range of about 12 to about 14 arcsec. As seen in FIG. 1, the (10.2) Rocking curve FWHM for the samples in generations 1 through 16 was consistently in the range of about 11 to about 42 arcsec. This demonstrated that seed lines prepared using grown polycrystalline AlN mass as described herein as a source material can have x-ray characteristics that remain substantially consistent or actually improve over a plurality of generations, particularly over three or more generations. This can be achieved while simultaneously expanding the size of the seeds in the subsequent generations and improving the overall quality of the available seeds over time.

In some embodiments, the present disclosure thus can provide an AlN seed that is suitable for iterative growth of further generations of single crystal AlN. Such AlN seed can be derived from a previous generation AlN single crystal. In particular embodiments, the AlN seed can be characterized in that the (00.2) X-ray diffraction (XRD) Rocking curve full width at half maximum (FWHM) for a seed line arising from the AlN seed changes by no more than 10 arc seconds over at least three generations, at least five generations, at least 10 generations, or at least 15 generations of the iterative growth. Preferably, the (00.2) XRD Rocking curve FWHM changes by no more than 7 arc seconds or by no more than 5 arc seconds over at least three generations, at least five generations, at least 10 generations, or at least 15 generations of the iterative growth. In other embodiments, the AlN seed can be characterized in that the (10.2) X-ray diffraction (XRD) Rocking curve full width at half maximum (FWHM) for a seed line arising from the AlN seed changes by no more than 50 arc seconds over at least three generations, at least five generations, at least 10 generations, or at least 15 generations of the iterative growth. Preferably, the (10.2) XRD Rocking curve FWHM changes by no more than 45 arc seconds or by no more than 30 arc seconds over at least three generations, at least five generations, at least 10 generations, or at least 15 generations of the iterative growth.

The AlN seed that can beneficially be utilized in the iterative growth of multi-generational single crystal AlN can be specifically derived from a previous generation AlN single crystal. In particular, the AlN seed can be a fraction of a previous generation single crystal AlN grown by PVT using an AlN source material that comprises a grown polycrystalline AlN mass as otherwise described herein. As an example, the grown polycrystalline AlN mass can be a mass that has been grown to have a thickness of about 2.5 cm or greater, to have at least one lateral dimension of about 3 cm or greater, to have an N/Al molar ratio of about 1, to have a relative density of at least 98%, and to have an aluminum nitride purity of at least 99% by weight.

In further embodiments, the present disclosure further can provide a process for multi-generational AlN single crystal seeded growth. Such methods can comprise iteratively growing a next generation AlN single crystal using a seed from a previous generation AlN single crystal. Preferably, the multi-generational growth can utilize a grown polycrystalline AlN mass of a quality as described herein. In particular, the grown polycrystalline AlN can be of a quality such that physical AlN single crystal size and at least one measure of single crystal AlN crystalline quality does not substantially decrease across at least three generations of the iterative growth. Each AlN single crystal arising from the iterative growth can be characterized by the XRD data otherwise described herein as a measure of the reproducibility of the method and the maintained quality of the grown materials.

Many modifications and other embodiments of the disclosure will come to mind to one skilled in the art to which this disclosure pertains having the benefit of the teachings presented in the foregoing descriptions and the associated drawings. Therefore, it is to be understood that the disclosure is not to be limited to the specific embodiments disclosed herein and that modifications and other embodiments are intended to be included within the scope of the appended claims. Although specific terms are employed herein, they are used in a generic and descriptive sense only and not for purposes of limitation.

1. A process for producing a single crystal Aluminum Nitride article comprising physical vapor transport (PVT) growth of the single crystal Aluminum Nitride article using a source material comprising a grown polycrystalline Aluminum Nitride mass.

2. The process according to claim 1, wherein the grown polycrystalline Aluminum Nitride mass exhibits one or more of:
a) a carbon content of less than 1000 ppm;
b) a silicon content of less than 1000 ppm;
c) an oxygen content of less than 1000 ppm;
d) an N/A1 molar ratio of about 1;
e) a relative density of at least 98%;
f) an aluminum nitride purity of at least 99% by weight.

3. The process according to claim 1, wherein the grown polycrystalline Aluminum Nitride mass is a hydride vapor phase epitaxy (HVPE) grown mass or a physical vapor deposition (PVD) grown mass.

4. A source material adapted for use in a physical vapor transport (PVT) growth process, the source material comprising a grown polycrystalline Aluminum Nitride mass that has been grown to have a thickness of about 2.5 cm or greater, to have at least one lateral dimension of about 12.5 cm or greater, to have an N/Al molar ratio of about 1, to have a relative density of at least 99%, and to have an aluminum nitride purity of at least 98% by weight.

5. The source material according to claim 4, wherein the grown polycrystalline Aluminum Nitride mass has been grown to have one or more of:
a) a carbon content of less than 1000 ppm;
b) a silicon content of less than 1000 ppm;
c) an oxygen content of less than 1000 ppm.

6. The source material according to claim 4, wherein the grown polycrystalline Aluminum Nitride mass has been grown to a diameter of about 12.5 cm or greater.

7. The source material according to claim 4, wherein the grown polycrystalline Aluminum Nitride mass has been grown to have an average grain size of about 0.5 mm to about 2 mm.

8. The source material according to claim 4, wherein the grown polycrystalline Aluminum Nitride mass is a hydride vapor phase epitaxy (HVPE) grown mass or a physical vapor deposition (PVD) grown mass.

9. A process for producing an Aluminum Nitride (AlN) single crystal via vapor phase transport (PVT), the process comprising:
providing an AlN source material and an AlN seed within a reactor in a spaced apart orientation; and
heating the AlN source material in a manner sufficient to form volatilized species from the AlN source material for transport to the AlN seed;
wherein the AlN source material comprises a grown polycrystalline AlN mass that has been grown to have a thickness of about 2.5 cm or greater, to have at least one lateral dimension of about 3 cm or greater, to have an N/Al molar ratio of about 1, to have a relative density of at least 98%, and to have an aluminum nitride purity of at least 99% by weight.

10. An AlN single crystal produced according to the process of claim 9, wherein the AlN single crystal is free or substantially free of one or a plurality of the following: inclusions, cracks, misoriented grains, domain boundaries, and polycrystals.

11. An AlN single crystal produced according to the process of claim 9, wherein the single crystal AlN has an optical absorption coefficient (alpha) at 265 nm of less than 100 cm⁻¹.

12. An AlN single crystal produced according to the process of claim 9, wherein the AlN single crystal has an average dislocation density that is less than 10⁻⁴ cm⁻² over the entire surface area of a single crystal that is larger than 20 mm diameter.

13. An AlN single crystal produced according to the process of claim 9, wherein the AlN single crystal has a boule height of greater than 2 cm.

14. An AlN single crystal produced according to the process of claim 9, wherein the AlN single crystal is larger than 25 mm in diameter and has a top surface entirely free of crystallographic tilt-domains greater than 30 arc-sec as measured by high resolution triple axis x-ray diffraction.

15. An Aluminum Nitride (AlN) seed that is derived from an AlN single crystal produced according to the process of claim 9.

16. An Aluminum Nitride (AlN) seed suitable for iterative growth of further generations of single crystal AlN, wherein:
the AlN seed comprises a fraction of a previous generation single crystal AlN; and
the (00.2) X-ray diffraction (XRD) Rocking curve full width at half maximum (FWHM) for a seed line arising from the AlN seed changes by no more than 10 arc seconds over at least three generations of the iterative growth.

17. The AlN seed of claim 16, wherein the AlN seed is a fraction of a previous generation AlN single crystal by a vapor phase transport (PVT) process using an AlN source material that comprises a grown polycrystalline AlN mass that has been grown to have a thickness of about 2.5 cm or greater, to have at least one lateral dimension of about 3 cm or greater, to have an N/Al molar ratio of about 1, to have a relative density of at least 98%, and to have an aluminum nitride purity of at least 99% by weight.

18. A process for multi-generational Aluminum Nitride (AlN) single crystal seeded growth, the method comprising iteratively growing a next generation AlN single crystal using a seed from a previous generation AlN single crystal, said iterative growing utilizing a grown polycrystalline AlN mass of a suitable quality such that physical AlN single crystal size and at least one measure of single crystal AlN crystalline quality does not substantially decrease across at least three generations of the iterative growth.

19. The process for multi-generational AlN single crystal seeded growth according to claim 18, wherein (00.2) X-ray diffraction (XRD) Rocking curve full width at half maximum (FWHM) for each AlN single crystal arising from the iterative growth changes by no more than 10 arc seconds over at least three generations of the iterative growth.

20. The process for multi-generational AlN single crystal seeded growth according to claim 18, wherein the grown polycrystalline AlN mass has been grown to have a thickness of about 2.5 cm or greater, to have at least one lateral dimension of about 3 cm or greater, to have an N/Al molar ratio of about 1, to have a relative density of at least 98%, and to have an aluminum nitride purity of at least 99% by weight.
